(19) United States
(12) Patent Application Publication
(10) Pub. No.: US 2024/0411943 A1
(43) Pub. Date: Dec. 12, 2024

(54) SYSTEMS AND METHODS FOR FOUNDATION MAPPING AND REMEDIATION

(71) Applicant: Terabase Energy, Inc., Berkeley, CA (US)

(72) Inventors: Adam Hansel, Davis, CA (US); Soren Jensen, Corte Madera, CA (US)

(73) Assignee: Terabase Energy, Inc., Berkeley, CA (US)

(21) Appl. No.: 18/208,038

(22) Filed: Jun. 9, 2023

(51) Int. Cl. G06F 30/13

(52) U.S. Cl. CPC G06F 30/13

(57) ABSTRACT

In a large construction site, it can be very challenging to maintain precise installation for multiple piles. If the piles are not installed accurately, subsequent installation process may have to be changed, adjusted, or adapted due to the actual pile construction. Validating installed piles accurately is a very complex and laborious process. System and method embodiments of pile mapping and remediation are disclosed. Three dimensional scanning is used to establish a point cloud for each pile. The point cloud is used for calculating pile installation parameters, which are compared to designed parameters to determine parameter deviations and to generate remediation schemes, which may involve adjust subsequent installation markings or pile re-installation. The implementation of pile mapping and remediation facilitates an on-site installation process with improved efficiency.

### TECHNICAL FIELD

The present disclosure relates generally to foundation mapping and remediation. More particularly, the present disclosure relates to foundation mapping and remediation that facilitates an on-site installation process for large construction sites.

### BACKGROUND

The importance of solar power systems is well understood by one of skill in the art. Government agencies and companies are scaling the size and number of solar solutions within their energy infrastructure. This transition from traditional fossil fuel energy systems to solar energy solutions presents several challenges. One challenge is cost-effective management of the construction process and the ability to improve on-site installation efficiency during the construction process.

In a large construction site, e.g., a large-scale solar farm construction site, hundreds or thousands of piles are driven into the ground to provide a foundation for a solar racking system. The placement and orientation of the piles are vital for the subsequent installation of the solar racking system. The installation tolerances of the piles are typically ±0.5 inch vertically and up to ±1.5 to 3 inches in the lateral directions. Piles are typically installed with twist tolerances on the order of 1.0° to 3° and up to 3° to 5° dependent on direction.

It can be very challenging to maintain consistent installation processes at each point of installation within a construction site across large areas. If the piles are not installed consistently or accurately, the subsequent installation process may have to be changed, adjusted, or adapted due to the actual pile construction. In the worst scenario, the subsequent installation process may even become impossible if the piles are installed poorly and the piles will have to be remediated or reinstalled

Validating the installed piles is a very complex and laborious process even with modern advanced technology like Differential Global Positioning System (DGPS) or TotalStations. At least three points are needed on each pile to accurately determine it location and orientation. Given the large number of piles in a construction site, it is very time-consuming to manually validate the installation accuracy of each pile, let alone provide effective remediation when one or more piles have installation deviations.

What is needed are systems, devices and methods that validate installed piles and/or provide remediation suggestions in case of inconsistent installation to facilitate efficient on-site installation of solar racking systems for large construction sites.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that the description is not intended to limit the scope of the invention to these particular embodiments. Items in the figures may be not to scale.

FIGURE (“FIG.”) 1 shows a three-dimensional (3D) scanning for multiple installed piles in a construction site in accordance with various embodiments of the invention.

FIG. 2 is a perspective view of a pile in accordance with various embodiments of the invention.

FIG. 3 is a perspective view of a point cloud for an installed pile in accordance with various embodiments of the invention.

FIG. 4 is a process of pile scanning and validation in accordance with various embodiments of the invention.

FIG. 5 is a perspective view of default markers and adjusted markers on an installed pile in accordance with various embodiments of the invention.

FIG. 6 is a perspective view of a bracket installed on a pile based on an adjusted marker in accordance with various embodiments of the invention.

FIG. 7 is a perspective view of a torque tube installed on a row of piles via multiple brackets in accordance with various embodiments of the invention.

FIG. 8 is a process of remediating installed piles in accordance with various embodiments of the invention.

FIG. 9 is an alternative process of remediating installed piles in accordance with various embodiments of the invention.

FIG. 10 is a simplified block diagram of a computing device in accordance with various embodiments of the invention.

### DETAILED DESCRIPTION OF EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be implemented in a variety of ways, such as a process, an apparatus, a system, a device, or a method.

Components, or features, shown in diagrams are illustrative of exemplary embodiments of the invention and are meant to avoid obscuring the invention. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in a variety of embodiments for foundation mapping and/or remediation.

Furthermore, connectivity between components or systems within the figures are not intended to be limited to direct connections. Also, components may be integrated together or be discrete prior to construction of a foundation mapping and/or remediation system.

Reference in the specification to “one embodiment,” “preferred embodiment,” “an embodiment,” or “embodiments” means that a particular feature, structure, characteristic, or function described in connection with the embodiment is included in at least one embodiment of the invention and may be in more than one embodiment. Also, the appearances of the above-noted phrases in various places in the specification are not necessarily all referring to the same embodiment or embodiments.

The use of certain terms in various places in the specification is for illustration and should not be construed as limiting. A component, function, or structure is not limited to a single component, function, or structure; usage of these terms may refer to a grouping of related components, functions, or structures, which may be integrated and/or discrete.

Further, it shall be noted that: (1) certain components or steps may be optional; (2) components or steps may not be limited to the specific description set forth herein; (3) certain components or steps may be assembled/combined differently; and (4) certain steps may be performed concurrently or in sequence.

Furthermore, it shall be noted that many embodiments described herein are given in the context of the assembly and installation of large numbers of solar panels within a system, but one skilled in the art shall recognize that the teachings of the present disclosure may apply to other large and complex construction sites other than solar farms.

In this document, “a large-scale solar farm” may be referred to as a solar power plant site having hundreds or more grounding piles as construction foundations. The word “pile” refers to a grounded pole, column, or beam that is partially inserted into ground and served as a foundation for subsequent constructions, such as brackets and/or torque tubes for a solar system. The term “solar table” refers to a structural assembly comprising one or more photovoltaic (PV) modules and/or one or more panel frames (or purlins) for PV module support. Some types of solar tables may have electrical harnesses and supplemental structure that allows them to connect to other solar tables or foundations/piles while other types do not have this supplemental structure.

FIG. 1 shows a three-dimensional (3D) scanning for multiple installed piles in a construction site in accordance with various embodiments of the invention. A plurality of piles are installed in a pattern of one or more rows, with each row 105 comprising multiple piles 110 to accommodate subsequent installations. For example, each row may be used to securely support a torque tube 130, on which multiple solar panels may be installed. Each row may have 10-15 piles spanning a distance of 350-400 feet. The rows are typically separated up to 22 feet.

The multiple piles in each row have to meet one or more predetermined installation tolerances, e.g., a vertical (z-direction) deviation, a lateral (x-direction and/or y-direction) deviation, orientation deviation, etc., such that the torque tube may be securely installed on each pile. The installation tolerances of the piles are typically +0.5 inch vertically, up to +1.5 to 3 inches in the lateral directions, and up to 3° to 5° for twist toleration.

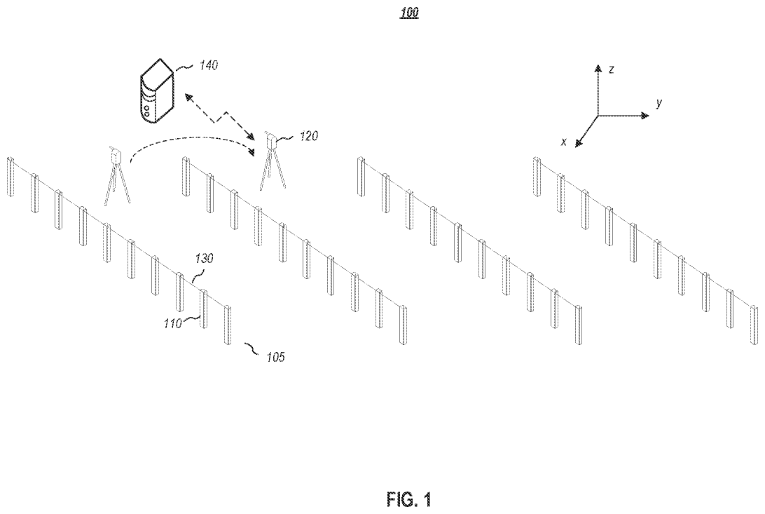

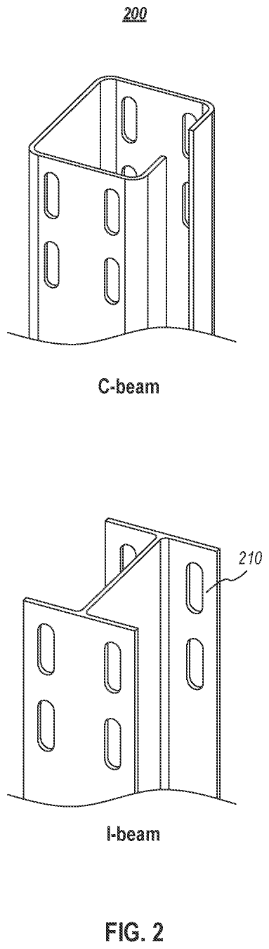

FIG. 2 is a perspective view of a pile in accordance with various embodiments of the invention. The pile is typically made from I-beams having a W-profile (or H-profile) or a C-beam having a C-profile. The pile may comprise a plurality of slots or holes 210 to facilitate the installation of brackets for torque tube support. The piles may have varied lengths and sizes, with a typical length of 4-5 feet above ground and 4-10 feet embedded underground.

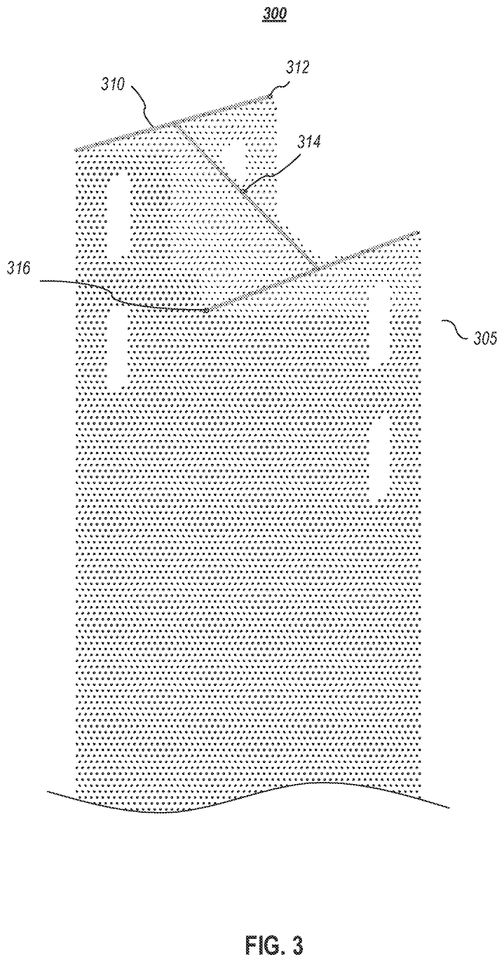

Referring back to FIG. 1, to validate the installed piles, a 3D scanner 120 is used to scan the plurality of piles to create a point cloud for each pile in each row. For better scanning, the scanner may scan two to four rows at a time and then move to a different location, as shown in FIG. 1, to scan another batch of rows. The 3D scanner may be a light detection and ranging (LIDAR) scanner with an accuracy of 3/32-⅛″ (2-3 mm) over distances of 500 feet. The point clouds for the plurality of piles may be stored locally within the 3D scanner or stored in a separate storage. The point clouds for the plurality of piles are accessible by a computing device 140, which may be a workstation (e.g., a laptop) deployed on-site, a server that couples to the 3D scanner, a cloud server, or an embedded computer in a mobile device that can be carried by a LIDAR operator, for further processing. FIG. 3 depicts a point cloud for a pile in accordance with various embodiments of the invention. The point cloud 305 comprises a plurality of date points, as shown FIG. 3, with the number of data points depending on scanning resolution and pile specification (high, width, etc.).

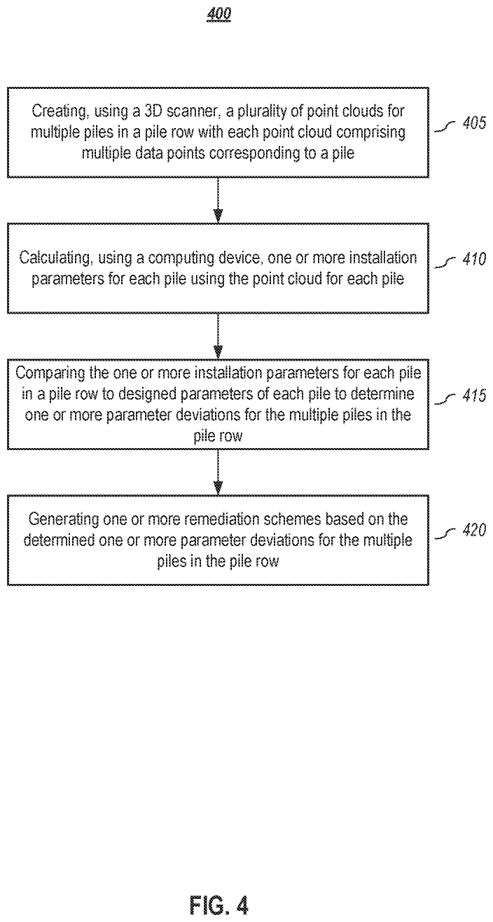

FIG. 4 is a process of pile scanning and validation in accordance with various embodiments of the invention. In step 405, a plurality of point clouds are created, using a 3D scanner, for multiple piles in a pile row, with each point cloud comprising multiple data points corresponding to a pile. In step 410, a computing device calculates one or more installation parameters for each pile, e.g., pile positions in x, y, and z coordinates, pile roll, pile pitch, pile yaw, etc., using the point cloud for each pile. Various algorithms may be adopted for such calculation, including extracting and fitting characteristics of a pile to identify important features of exposed section of the pile to determine installation parameters. The features may be edges, intersection of edges, ends of edges, corners, holes, or slots in the pile.

For example, the computing device may identify one or more characteristic data points among the multiple data points in each point cloud and then use the one or more characteristic data points to perform the calculation. As shown in FIG. 3, the computing device identifies three data points 312, 314, and 316 on a top layer 310 of the point cloud 305. The data point 314 may be a geometry center of the top layer and used to identify pile positions in x, y, and z coordinates for the pile. The data points 312 and 316 may be two data points at opposite corners of the top layer and used, together with the data point 314, to identify pile roll, pile pitch, and pile yaw. One skilled in the art shall understand other characteristic data points, e.g., data points at different layers, may also be used for calculating installation parameters.

In step 415, the computing device compares the one or more installation parameters for each pile in a pile row to the designed parameters of each pile to determine one or more parameter deviations of the multiple piles in the pile row. The designed parameters may be theoretic or default parameters for each pile, such as designed pile positions, pile roll, pile pitch, and pile yaw. Ideally, the parameter deviations would be zero when each pile is perfectly installed. Practically, due to inevitable installation errors, there always are some parameter deviations in one or more piles among the multiple piles in a row.

In step 420, one or more remediation schemes are generated based on the determined one or more parameter deviations of the multiple piles in the pile row. The remediation schemes may be generated using the same computing device that performs installation parameter calculation and parameter deviation determination or using a separate computing device specifically handling remediation generation. The remediation schemes may be re-installations for one or more piles that have at least one parameter deviation above a threshold, one or more offsets for subsequent installation positions on one or more piles, or a combination or both.

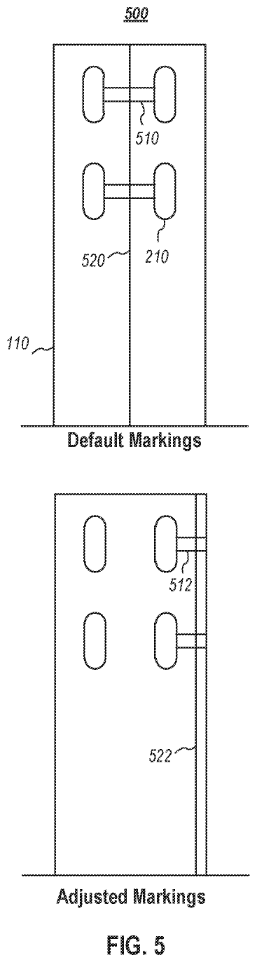

FIG. 5 is a perspective view of default markers and adjusted markers on an installed pile in accordance with various embodiments of the invention. An installed pile 110 has one or more default markers for subsequent installation of one or more brackets on the pile under an ideal scenario where the pile is installed perfectly with no parameter deviations (or parameter deviations as zero). The pile 110 comprises one or more slots 210 that are used for subsequent bracket installation on the pile. The default markers may comprise one or more horizontal markers 510 and one or more vertical markers 520 that are used to identify one or more reference points/lines for subsequent installations on the pile. For example, the horizontal markers 510 may be a line of alignment for a top edge of a bracket. Alternatively, the horizontal marker 510 may be referred to as a horizontal coordinate of an installation point for a bracket.

When one or more parameter deviations are identified for the pile 110, subsequent bracket installations on the pile shall be changed or updated as indicated by one or more adjusted markings, which may comprise one or more adjusted horizontal markers 512 and/or one or more vertical markers 522 that are used to identify one or more adjusted reference points/lines for subsequent installations on the pile. The one or more adjusted horizontal markers are determined based on one or more offsets, e.g., offsets in x, y, and z coordinates with respect to the one or more default markers.

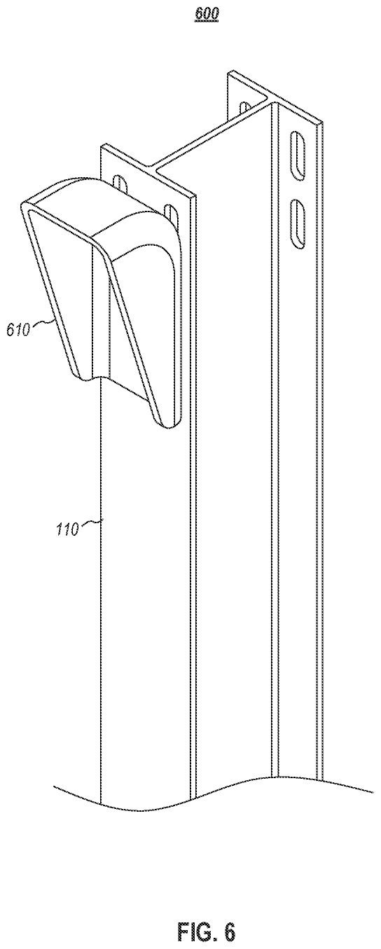

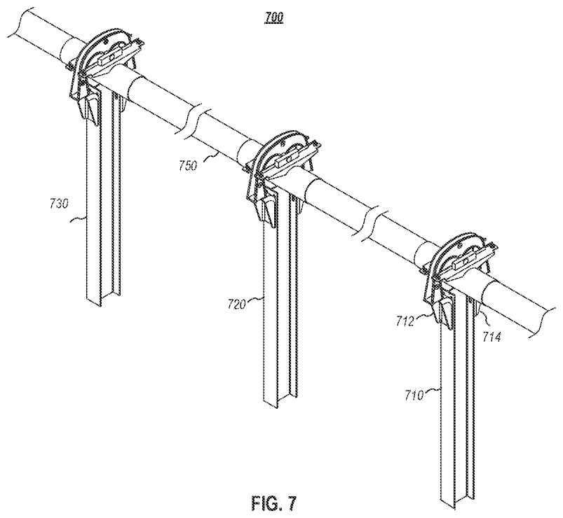

FIG. 6 depicts a perspective view of a bracket 610 installed on a pile 110 based on adjusted markers in accordance with various embodiments of the invention. FIG. 7 is a perspective view of a torque tube 750 installed on a row of piles comprising multiple piles 710, 720, 730, etc., via multiple brackets, e.g., 712, 714, in accordance with various embodiments of the invention. Mounted by the adjusted markings for bracket installations, the torque tube 750 may still be installed, within a torque tube installation error, on the multiple piles 710, 720, 730, even though some piles are installed with parameter deviations. Therefore, pile re-installation may be avoided, installation efficiency may be improved, and construction costs may be decreased.

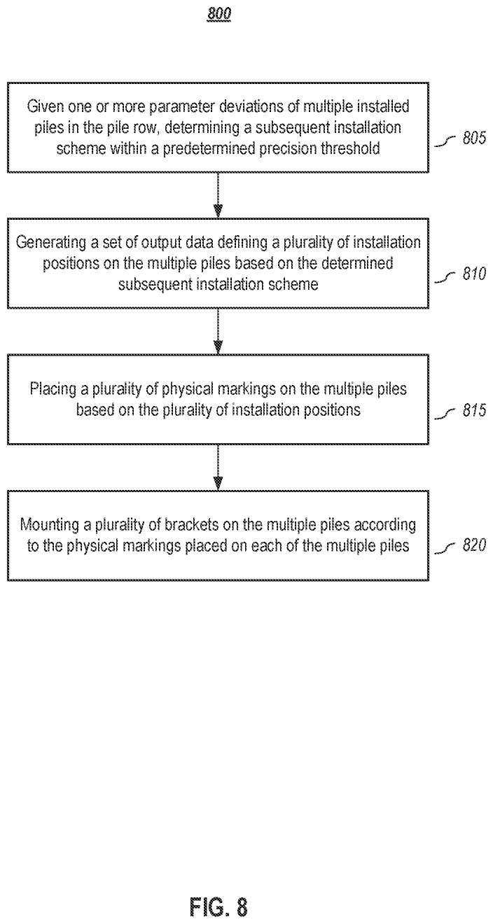

FIG. 8 is a process of remediating installed piles in accordance with various embodiments of the invention. In step 805, given one or more parameter deviations of multiple installed piles in the pile row, a second computing device determines a subsequent installation scheme, e.g., a torque tube installation scheme, within a predetermined precision threshold (e.g., a tube level and tube angle precision) such that the torque tube can be installed on the multiple installed piles. The second computing device may or may not be the same computing device that performs installation parameter calculation. In some embodiments, the subsequent installation scheme is determined with a priority for a highest precision for the subsequent installation scheme. In some other embodiments, the subsequent installation scheme may be determined with a priority of a highest possible precision within the predetermined precision threshold to engage all of the multiple piles for subsequent installation without requiring any pile re-installation. For example, the second computing device may choose a torque tube installation scheme with a precision of 3° orientation deviation (within a 5° threshold) to engage all installed piles for torque tube installation instead of choosing a torque tube installation scheme with a precision of 0.5° orientation deviation but not capable of engaging all installed piles. In one or more embodiments, the second computing device may use various algorithms, such as linear or polynomial interpolating, to determine the subsequent installation scheme.

In step 810, the second computing device generates a set of output data defining a plurality of installation positions on the multiple piles based on the determined subsequent installation scheme. The set of output data comprises one or more offsets for one or more installation parameters for one or more piles, among the multiple piles in a row. The one or more offsets may be applicable to one or more piles that have parameter deviations, to one or more piles that do not have parameter deviations, or to a mixture of piles with parameter deviations and without parameter deviations.

In step 815, a plurality of physical markings are placed on the multiple piles based on the plurality of installation positions. Physical markings on one pile may be default markings, adjusted markings with offsets for default markings, or a combination of both. In one or more embodiments, the physical markings are marked using a pile marker, which may be placed on top of a pile to mark bracket mounting positions on the pile. The pile marker may have a build-in Global Positioning System (GPS) or similar location sensor to automatically identify location, pile ID and position of markings for that specific pile, as well as determine whether the pile has been marked. Alternatively, the pile location/identification may be manually checked using a look-up table. During the check-up, the pile location and/or identification (ID) may be used to extract marking locations for that pile. For example, an individual pile may be identified using a GPS system or manual lookup. Based on an ID of the pile, one or more marking positions may be recalled from the calculations and marked on the pile either automatically or manually. In step 820, a plurality of brackets are mounted on the multiple piles according to the physical markings placed on each of the multiple piles.

In one or more embodiments, the one or more parameter deviations of multiple installed piles may be excessive. As a result, the second computing device may not be able to determine a subsequent installation scheme within a predetermined precision threshold for the multiple installed piles. As a result, the second computing device may need to propose a subsequent installation scheme involving re-installation of one or more piles.

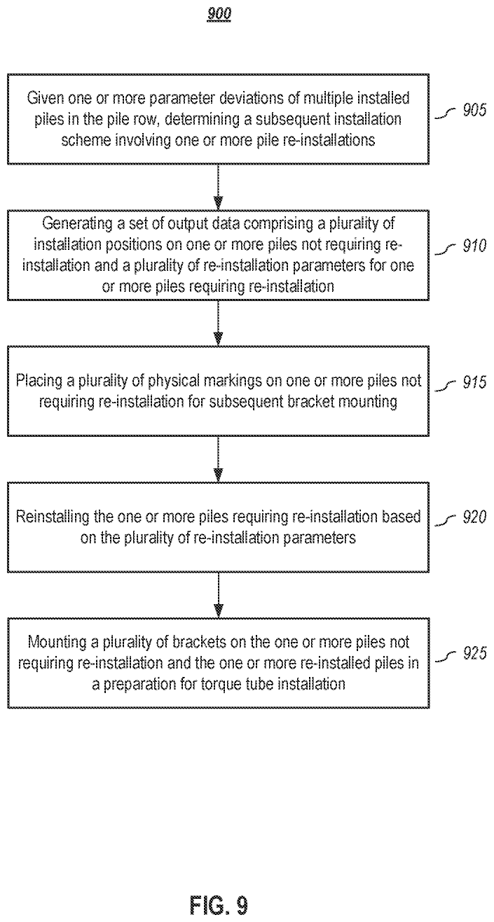

FIG. 9 is an alternative process of remediating installed piles involving pile re-installation in accordance with various embodiments of the invention. In step 905, given one or more parameter deviations of multiple installed piles in the pile row, the second computing device determines a subsequent installation scheme involving one or more pile re-installations to accommodate a torque tube installation within a predetermined precision threshold. In some embodiments, the subsequent installation scheme is determined with a priority for a highest precision for the subsequent installation scheme. In some other embodiments, the subsequent installation scheme may be determined with a priority of a minimum pile re-installation to meet the predetermined precision threshold.

In step 910, based on the determined subsequent installation scheme, the second computing device generates a set of output data comprising a plurality of installation positions on one or more piles, among the multiple piles, not requiring re-installation, and a plurality of re-installation parameters for one or more piles, among the multiple piles, requiring re-installation. The plurality of installation positions may comprises one or more offsets for one or more installation parameters for piles not requiring re-installation.

In step 915, a plurality of physical markings are placed, based on the plurality of installation positions, on one or more piles not requiring re-installation for subsequent bracket mounting. In step 920, the one or more piles requiring re-installation are re-installed based on the plurality of re-installation parameters. In step 925, a plurality of brackets are mounted on the one or more piles not requiring re-installation and the one or more re-installed piles in preparation for torque tube installation.

In one or more embodiments, aspects of the present patent document may be directed to, may include, or may be implemented on one or more computing systems. A computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data. For example, a computing system may be or may include a personal computer (e.g., laptop), tablet computer, mobile device (e.g., personal digital assistant (PDA), smartphone, phablet, tablet, etc.), smartwatch, server (e.g., blade server or rack server), a network storage device, camera, or any other suitable device and may vary in size, shape, performance, functionality, and price. The computing system may include random access memory (RAM), one or more processing resources such as a central processing unit (CPU) or hardware or software control logic, read-only memory (ROM), and/or other types of memory. Additional components of the computing system may include one or more drives (e.g., hard disk drive, solid-state drive, or both), one or more network ports for communicating with external devices as well as various input and output (I/O) devices, such as a keyboard, mouse, touchscreen, stylus, microphone, camera, trackpad, display, etc. The computing system may also include one or more buses operable to transmit communications between the various hardware components.

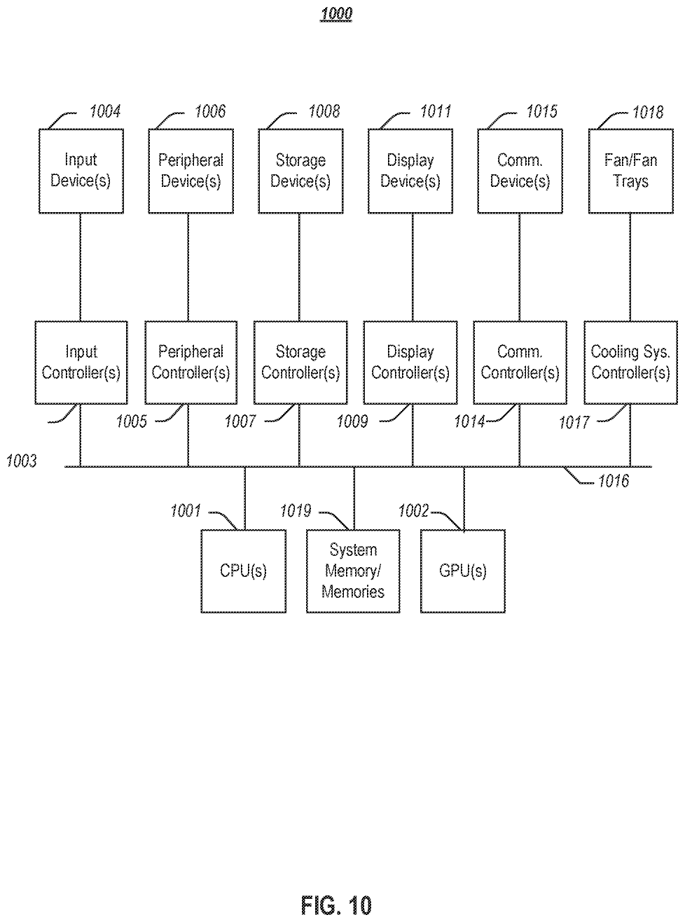

FIG. 10 depicts a simplified block diagram of a computing system, according to embodiments of the present disclosure. It will be understood that the functionalities shown for system 1000 may operate to support various embodiments of a computing system—although it shall be understood that a computing system may be differently configured and include different components, including having fewer or more components as depicted in FIG. 10.

As illustrated in FIG. 10, the computing system 1000 includes one or more CPUs 1001 that provide computing resources and control the computer. CPU 1001 may be implemented with a microprocessor or the like, and may also include one or more graphics processing units (GPU) 1002 and/or a floating-point coprocessor for mathematical computations. In one or more embodiments, one or more GPUs 1002 may be incorporated within the display controller 1009, such as part of a graphics card or cards. Thy system 1000 may also include a system memory 1019, which may comprise RAM, ROM, or both.

A number of controllers and peripheral devices may also be provided, as shown in FIG. 10. An input controller 1003 represents an interface to various input device(s) 1004. The computing system 1000 may also include a storage controller 1007 for interfacing with one or more storage devices 1008 each of which includes a storage medium such as magnetic tape or disk, or an optical medium that might be used to record programs of instructions for operating systems, utilities, and applications, which may include embodiments of programs that implement various aspects of the present disclosure. Storage device(s) 1008 may also be used to store processed data or data to be processed in accordance with the disclosure. The system 1000 may also include a display controller 1009 for providing an interface to a display device 1011, which may be a cathode ray tube (CRT) display, a thin film transistor (TFT) display, organic light-emitting diode, electroluminescent panel, plasma panel, or any other type of display. The computing system 1000 may also include one or more peripheral controllers or interfaces 1005 for one or more peripherals 1006. Examples of peripherals may include one or more printers, scanners, input devices, output devices, sensors, and the like. A communications controller 1014 may interface with one or more communication devices 1015, which enables the system 1000 to connect to remote devices through any of a variety of networks including the Internet, a cloud resource (e.g., an Ethernet cloud, a Fiber Channel over Ethernet (FCOE)/Data Center Bridging (DCB) cloud, etc.), a local area network (LAN), a wide area network (WAN), a storage area network (SAN) or through any suitable electromagnetic carrier signals including infrared signals. As shown in the depicted embodiment, the computing system 1000 comprises one or more fans or fan trays 1018 and a cooling subsystem controller or controllers 1017 that monitors thermal temperature(s) of the system 1000 (or components thereof) and operates the fans/fan trays 1018 to help regulate the temperature.

In the illustrated system, all major system components may connect to a bus 1016, which may represent more than one physical bus. However, various system components may or may not be in physical proximity to one another. For example, input data and/or output data may be remotely transmitted from one physical location to another. In addition, programs that implement various aspects of the disclosure may be accessed from a remote location (e.g., a server) over a network. Such data and/or programs may be conveyed through any of a variety of machine-readable media including, for example: magnetic media such as hard disks, floppy disks, and magnetic tape; optical media such as compact discs (CDs) and holographic devices; magneto-optical media; and hardware devices that are specially configured to store or to store and execute program code, such as application specific integrated circuits (ASICs), programmable logic devices (PLDs), flash memory devices, other non-volatile memory (NVM) devices (such as 3D XPoint-based devices), and ROM and RAM devices.

Aspects of the present disclosure may be encoded upon one or more non-transitory computer-readable media with instructions for one or more processors or processing units to cause steps to be performed. It shall be noted that non-transitory computer-readable media shall include volatile and/or non-volatile memory. It shall be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that embodiments of the present disclosure may further relate to computer products with a non-transitory, tangible computer-readable medium that has computer code thereon for performing various computer-implemented operations. The media and computer code may be those specially designed and constructed for the purposes of the present disclosure, or they may be of the kind known or available to those having skill in the relevant arts. Examples of tangible computer-readable media include, for example: magnetic media such as hard disks, floppy disks, and magnetic tape; optical media such as CDs and holographic devices; magneto-optical media; and hardware devices that are specially configured to store or to store and execute program code, such as ASICs, PLDs, flash memory devices, other non-volatile memory devices (such as 3D XPoint-based devices), and ROM and RAM devices. Examples of computer code include machine code, such as produced by a compiler, and files containing higher level code that are executed by a computer using an interpreter. Embodiments of the present disclosure may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the present disclosure. One skilled in the art will also recognize that a number of the elements described above may be physically and/or functionally separated into modules and/or sub-modules or combined together.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

What is claimed is:

1. A method for foundation mapping and remediation comprising:
creating, using a three-dimensional scanner, a plurality of point clouds for multiple piles in a pile row, with each point cloud comprising multiple data points corresponding to a pile;
calculating, using a computing device, one or more installation parameters for each pile using the point cloud for each pile;
comparing the one or more installation parameters for each pile to designed parameters of each pile to determine one or more parameter deviations for the multiple piles in the pile row; and
generating one or more remediation schemes based on the determined one or more parameter deviations for the multiple piles in the pile row.

2. The method of claim 1 wherein the one or more installation parameters comprise one or more of:
a pile position in x coordinate;
a pile position in y coordinate;
a pile position in z coordinate;
a pile roll;
a pile pitch; and
a pile yaw.

3. The method of claim 1 wherein calculating one or more installation parameters for each pile using the point cloud for each pile comprising:
identifying one or more characteristic data points among the multiple data points in each point cloud; and
using the one or more characteristic data points to perform the calculation.

4. The method of claim 3 wherein the one or more characteristic data points comprise a geometry center of a top layer in the point cloud and two data points at opposite corners of the top layer.

5. The method of claim 1 wherein generating one or more remediation schemes based on the determined one or more parameter deviations for the multiple piles in the pile row comprising:
determining a subsequent installation scheme within a predetermined precision threshold to engage all of the multiple piles in the pile row for subsequent installation without requiring any pile re-installation;
generating a set of output data defining a plurality of installation positions on the multiple piles based on the determined subsequent installation scheme, the set of output data comprises one or more offsets for one or more installation parameters for one or more piles, among the multiple piles in a row; and
placing a plurality of physical markings on the multiple piles based on the plurality of installation positions.

6. The method of claim 5 wherein the physical markings on the multiple piles are default markings, adjusted markings with offsets for default markings, or a combination of both.

7. The method of claim 5 wherein the one or more offsets are applicable to one or more piles that have parameter deviations, to one or more piles that do not have parameter deviations, or to a mixture of piles with parameter deviations and without parameter deviations.

8. The method of claim 1 wherein generating one or more remediation schemes based on the determined one or more parameter deviations for the multiple piles in the pile row comprising:
determining a subsequent installation scheme involving one or more pile re-installations to accommodate subsequent installation within a predetermined precision threshold; and
generating a set of output data comprising a plurality of installation positions on one or more piles not requiring re-installation and a plurality of re-installation parameters for one or more piles requiring re-installation.

9. The method of claim 8 wherein the subsequent installation scheme is determined with a priority for a highest precision for the subsequent installation scheme.

10. The method of claim 8 wherein the subsequent installation scheme is determined with a priority of a minimum pile re-installation to meet the predetermined precision threshold.

11. A non-transitory computer-readable medium or media comprising one or more sequences of instructions which, when executed by at least one processor, causes steps for foundation mapping and remediation comprising:
receiving a plurality of point clouds, created by a three-dimensional scanner, for multiple piles in a pile row, with each point cloud comprising multiple data points corresponding to a pile;
calculating one or more installation parameters for each pile using the point cloud for each pile;
comparing the one or more installation parameters for each pile to designed parameters of each pile to determine one or more parameter deviations for the multiple piles in the pile row; and
generating one or more remediation schemes based on the determined one or more parameter deviations for the multiple piles in the pile row.

12. The non-transitory computer-readable medium or media of claim 11 wherein the one or more installation parameters comprise one or more of:
a pile position in x coordinate;
a pile position in y coordinate;
a pile position in z coordinate;
a pile roll;
a pile pitch; and
a pile yaw.

13. The non-transitory computer-readable medium or media of claim 11 wherein the step of calculating one or more installation parameters for each pile using the point cloud for each pile comprises:
identifying one or more characteristic data points among the multiple data points in each point cloud; and
using the one or more characteristic data points to perform the calculation.

14. The non-transitory computer-readable medium or media of claim 13 wherein the one or more characteristic data points comprise a geometry center of a top layer in the point cloud and two data points at opposite corners of the top layer.

15. The non-transitory computer-readable medium or media of claim 11 wherein the step of generating one or more remediation schemes based on the determined one or more parameter deviations for the multiple piles in the pile row comprises:
determining a subsequent installation scheme within a predetermined precision threshold to engage all of the multiple piles in the pile row for subsequent installation without requiring any pile re-installation; and
generating a set of output data defining a plurality of installation positions on the multiple piles based on the determined subsequent installation scheme, the set of output data comprises one or more offsets for one or more installation parameters for one or more piles, among the multiple piles in a row.

16. The non-transitory computer-readable medium or media of claim 15 wherein the subsequent installation scheme is a scheme for installing a torque tube on the multiple piles in a pile row.

17. The non-transitory computer-readable medium or media of claim 15 wherein the one or more offsets are applicable to one or more piles that have parameter deviations, to one or more piles that do not have parameter deviations, or to a mixture of piles with parameter deviations and without parameter deviations.

18. The non-transitory computer-readable medium or media of claim 11 wherein the step of generating one or more remediation schemes based on the determined one or more parameter deviations for the multiple piles in the pile row comprises:
determining a subsequent installation scheme involving one or more pile re-installations to accommodate subsequent installation within a predetermined precision threshold; and
generating a set of output data comprising a plurality of installation positions on one or more piles not requiring re-installation and a plurality of re-installation parameters for one or more piles requiring re-installation.

19. The non-transitory computer-readable medium or media of claim 18 wherein the subsequent installation scheme is determined with a priority for a highest precision for the subsequent installation scheme.

20. The non-transitory computer-readable medium or media of claim 19 wherein the subsequent installation scheme is determined with a priority of a minimum pile re-installation to meet the predetermined precision threshold.
